(19) United States
(12) Patent Application Publication
(10) Pub. No.: US 2015/0201495 A1
(43) Pub. Date: Jul. 16, 2015

(54) STACKED CONDUCTIVE INTERCONNECT INDUCTOR

(71) Applicant: QUALCOMM Incorporated, San Diego, CA (US)

(72) Inventors: Daeik Daniel KIM, San Diego, CA (US); Mario Francisco VELEZ, San Diego, CA (US); Chengjie ZUO, Santee, CA (US); Changhan Hobie YUN, San Diego, CA (US); Jonghae KIM, San Diego, CA (US); Matthew Michael NOWAK, San Diego, CA (US)

(73) Assignee: QUALCOMM Incorporated, San Diego, CA (US)

(21) Appl. No.: 14/155,187

(22) Filed: Jan. 14, 2014

(51) Int. Cl. H05K 1/14; H05K 3/06; H05K 1/18

(52) U.S. Cl. CPC H05K 1/141; H05K 1/181; H05K 3/064

(57) ABSTRACT

An integrated circuit device includes a first substrate supporting a pair of conductive interconnects, for example pillars. The device also includes a second substrate on the pair of conductive interconnects. The pair of conductive interconnects is arranged to operate as a first 3D solenoid inductor. The device further includes a conductive trace coupling the pair of conductive interconnects to each other.

### TECHNICAL FIELD

The present disclosure generally relates to the fabrication of integrated circuits (ICs). More specifically, one aspect of the present disclosure relates to a stacked conductive interconnect inductor.

### BACKGROUND

The process flow for semiconductor fabrication of integrated circuits (ICs) may include front-end-of-line (FEOL), middle-of-line (MOL), and back-end-of-line (BEOL) processes. The front-end-of-line process may include wafer preparation, isolation, well formation, gate patterning, spacer, extension and source/drain implantation, silicide formation, and dual stress liner formation. The middle-of-line process may include gate contact formation. The back-end-of-line processes may include a series of wafer processing steps for interconnecting the semiconductor devices created during the front-end-of-line and middle-of-line processes.

Successful fabrication and qualification of modern semiconductor chip products involves an interplay between the materials and the processes employed. In particular, the formation of conductive material plating for the semiconductor fabrication in the back-end-of-line processes is an increasingly challenging part of the process flow. This is particularly true in terms of maintaining a small feature size. The same challenge of maintaining a small feature size also applies to passive on glass (POG) technology, where high-performance components such as inductors and capacitors are built upon a highly insulative substrate that may also have a very low loss.

### SUMMARY

In one aspect, an integrated circuit device includes a first substrate supporting a first pair of conductive interconnects. The device also includes a second substrate on the first pair of conductive interconnects. The first pair of conductive interconnects are arranged to operate as part of a first 3D solenoid inductor. The device further includes a first conductive trace coupling the first pair of conductive interconnects to each other.

Another aspect discloses an integrated circuit device that includes a first substrate supporting a first pair of conductive interconnects and a second pair of conductive interconnects. The device also includes a second substrate stacked on the first and second pair of conductive interconnects. The second substrate supports a third pair of conductive interconnects and a fourth pair of conductive interconnects. The second substrate also includes a pair of vias coupling the second pair of conductive interconnects to the fourth pair of conductive interconnects. The device further includes a third substrate stacked on the third and fourth pairs of conductive interconnects. The device includes a first conductive trace coupling the first pair of conductive interconnects to each other to operate as a first stacked 3D solenoid inductor. The device also includes a second conductive trace coupling the third pair of conductive interconnects to each other to operate as a second stacked 3D solenoid inductor. The device further includes a third conductive trace coupling one of the second or fourth pair of conductive interconnects to each other to operate as a third stacked 3D solenoid inductor.

In another aspect, a back end of line processing method to fabricate an inductive device is disclosed. The method includes fabricating a first pair of conductive interconnects on a first substrate. The method also includes placing a second substrate on the first pair of conductive interconnects. The first pair of conductive interconnects is arranged to operate as a first 3D solenoid inductor. The method further includes fabricating a first conductive trace coupling the first pair of conductive interconnects to each other.

Another aspect discloses an integrated circuit device that includes a first substrate supporting a first pair of means for interconnecting. The device also includes a second substrate on the first pair of interconnecting means. The first pair of interconnecting means are arranged to operate as a first 3D solenoid inductor. The device further includes a first conductive means coupling the first pair of interconnecting means to each other.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 shows a cross-sectional view illustrating a device having a typical single stack implementation of a 3D inductor.

FIG. 2 shows a cross-sectional view illustrating a device having a multiple stack implementation of a 3D inductor according to one aspect of the disclosure.

FIGS. 3A-3I show cross-sectional views illustrating steps of a process to fabricate a device having a multiple stack implementation of a 3D inductor according to one aspect of the disclosure.

FIG. 4 is a process flow diagram illustrating a process to fabricate a device having a multiple stack implementation of a 3D inductor according to one aspect of the disclosure.

FIG. 5 is a block diagram showing an exemplary wireless communication system in which a configuration of the disclosure may be advantageously employed.

FIG. 6 is a block diagram illustrating a design workstation used for circuit, layout, and logic design of a semiconductor component according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent to those skilled in the art, however, that these concepts may be practiced without these specific details. In some instances, well-known structures and components are shown in block diagram form in order to avoid obscuring such concepts. As described herein, the use of the term “and/or” is intended to represent an “inclusive OR”, and the use of the term “or” is intended to represent an “exclusive OR”.

Passive on glass devices involve high-performance inductor and capacitor components that have a variety of advantages over other technologies, such as surface mount technology or multi-layer ceramic chips. These advantages include being more compact in size and having smaller manufacturing variations. Passive on glass devices also involve a higher Q (or quality factor) value that meets stringent low insertion loss and low power consumption specifications. Devices such as inductors may be implemented as three-dimensional (3D) structures with passive on glass technologies. 3D inductors or other 3D devices may also experience a number of design constraints due to their 3D implementation.

Devices such as inductors may be implemented as three-dimensional (3D) structures. 3D inductors may also be fabricated as passive on glass devices. 3D inductors may also take the shape of a 3D solenoid inductor. Typically, only a single substrate, on a single level or a single stack, is used to fabricate a 3D inductor. Furthermore, the substrate thickness is fixed, leading to many design constraints when fabricating the inductor. In addition, 3D solenoid inductors may be magnetically coupled together in one 3D structure, and there may be multiple inductors on the same substrate. This may lead to space crowding issues and the limiting of the number of inductors that can be fit into a circuit. Also, the overall impedance for the circuit may increase, while the Q (or quality) factor for the 3D inductors may decrease.

There are a number of advantages associated with implementing 3D inductors as multiple stacks of pillars made of conductive interconnect material. By creating 3D inductors from vertical stacks of pillars, many more 3D inductors can be integrated into a given device or structure. In addition, the modulated vertical height of a 3D inductor made from stacks of pillars can add up to a high Q factor. Also, 3D inductors implemented as multiple stacks of pillars exhibit much larger inductance values. By implementing 3D inductors as pillar stacks, there is more space in a device to implement a center tap region that couples to all the 3D inductors within the device structure.

In one aspect of the disclosure, an integrated circuit device includes a 3D solenoid inductor formed from stacked layers of conductive interconnects. In one configuration, the integrated circuit device includes a first substrate supporting a first pair of conductive interconnects. The device also includes a second substrate stacked on the first pair of conductive interconnects. The first pair of conductive interconnects is arranged to operate as a first 3D solenoid inductor. The device further includes a first conductive trace coupling the first pair of conductive interconnects to each other.

In another aspect of the disclosure, the integrated circuit device includes a first substrate supporting a first pair of conductive interconnects and a second pair of conductive interconnects. The device also includes a second substrate stacked on the first and second pair of conductive interconnects. The second substrate supports a third pair of conductive interconnects and a fourth pair of conductive interconnects. The second substrate also includes a pair of vias coupling one of the first or second pair of conductive interconnects to one of the third or fourth pair of conductive interconnects to operate as a stacked 3D solenoid inductor. The device further includes a third substrate stacked on the third and fourth pair of conductive interconnects.

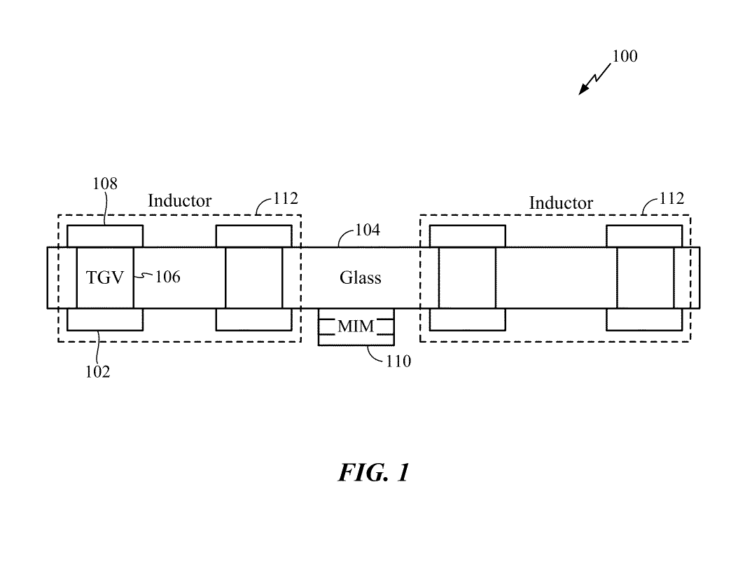

FIG. 1 shows a cross-sectional view illustrating a device 100 having a single stack implementation of a 3D inductor 112. A substrate 104, which may be made of glass, includes holes through the substrate 104. A through glass via (TGV) 106 is formed within the holes. The TGV 106 may be fully filled with a conductive material. Alternatively, a conformal filling of the TGV 106 may be performed to provide a shell-like partial filling of the conductive material within the TGV 106. The conductive material may be, for example, copper (Cu). A first conductive layer 102 and a second conductive layer 108 are positioned at opposite ends of the TGV 106 to form one half of the 3D inductor 112, which may be arranged in a solenoid shape. Two components are combined together to form the 3D inductor. Each component may include the first conductive layer 102, the second conductive layer 108 and the TGV 106. A metal-insulator-metal (MIM) capacitor 110 may be deposited on a surface of the substrate 104.

The single stack implementation of the 3D inductor 112 in FIG. 1 may have a fixed substrate thickness, which leads to a number of design constraints involving material selection, temperature and size. Also, the 3D inductors 112 clutter the substrate 104, which lowers both the overall impedance value and the Q (or quality) factor of the device 100.

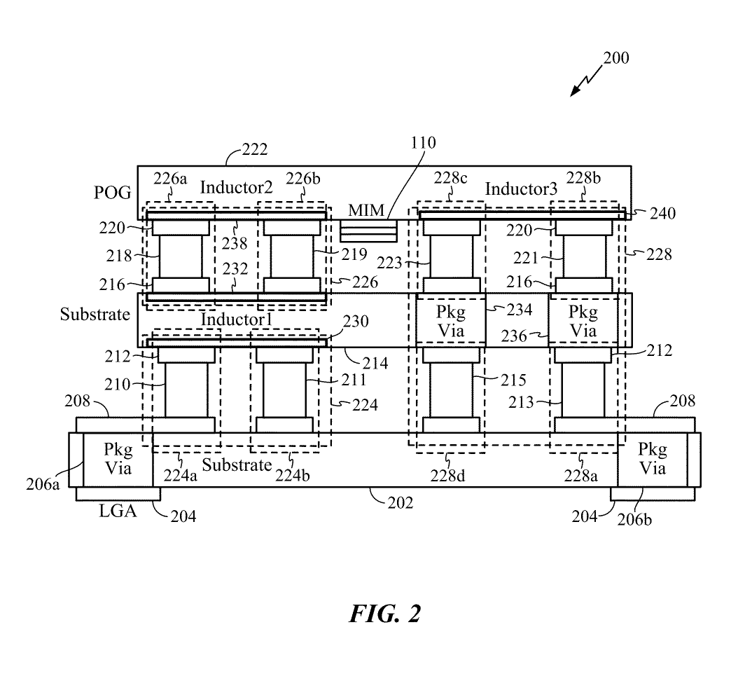

FIG. 2 shows a cross-sectional view illustrating a device 200 including a stacked implementation of a 3D inductor 228 according to one aspect of the disclosure. The device 200 includes a first substrate 202 having a left package via 206a and a right package via 206b. The package vias 206a and 206b are formed within the first substrate 202 and may be fully or partially filled with a conductive material, a polyimide material or may just be hollow. At one end of the package vias 206a and 206b is a land grid array (LGA) 204. The LGA 204 may also be a ball grid array (BGA). The LGA 204 is a type of surface-mount packaging for integrated circuits (ICs) that is notable for having the pins on the socket rather than the IC. At another end of the package vias 206a and 206b is a first conductive layer 208. The first conductive layer 208 also is in contact with a surface of the first substrate 202 in particular regions, as shown in FIG. 2.

First conductive pillars 210 and 211 made of a conductive material are in contact with the first conductive layer 208 on one end and a second conductive layer 212 on the other end. The second conductive pillars 213 and 215 are similar to the first conductive pillars 210 and 211 in that they are also in contact with the first conductive layer 208 on one end and the second conductive layer 212 on the other end. The second conductive layer 212 is deposited on and in contact with one surface of a second substrate 214. Within the second substrate 214, there is also a left second substrate package via 234 and a right second substrate package via 236. A third conductive layer 216 is deposited on another surface of the second substrate 214. Third conductive pillars 218 and 219 contact the third conductive layer 216 on one end and a fourth conductive layer 220 on the other end. The fourth conductive pillars 221 and 223 are similar to the third conductive pillars 218 and 219 in that they are also in contact with the third conductive layer 216 on one end and the fourth conductive layer 220 on the other end. The fourth conductive layer 220 is deposited on and in contact with one surface of the third substrate 222. There is also a metal-insulator-metal (MIM) capacitor 110 in contact with a surface of the third substrate 222.

FIG. 2 illustrates a first 3D inductor 224, a second 3D inductor 226 and a third 3D inductor 228 within the device 200. The first 3D inductor 224, the second 3D inductor 226 and/or the third 3D inductor 228 may each be a 3D solenoid inductor.

The first 3D inductor 224 includes the first conductive layer 208, first conductive pillars 210 and 211, the second conductive layer 212, and the first inductor trace 230. There are two regions that make up the first 3D inductor 224: a left first inductor region 224a and a right first inductor region 224b. Thus, the first 3D inductor 224 includes the leftmost portion of the first conductive layer 208, the leftmost of the first conductive pillars 210, the leftmost portion of the second conductive layer 212, the first inductor trace 230, the rightmost portion of the second conductive layer, a rightmost one of the first conductive pillars 211, and a rightmost portion of the first conductive layer 208.

The upside-down “U” loop for current flow in the first 3D inductor 224 is formed from the LGA 204 coupled to the left package via 206a through the first conductive layer 208 of the left first inductor region 224a, through the first conductive pillar 210 of the left first inductor region 224a, through the second conductive layer 212 of the left first inductor region 224a, through the first inductor trace 230, through the second conductive layer 212 of the right first inductor region 224b, through the first conductive pillar 211 of the right first inductor region 224b and through the first conductive layer 208 of the right first inductor region 224b to finally arrive at the first substrate 202. The upside-down U loop for the first 3D inductor 224 may also be formed in the opposite direction of what was just described.

Similarly, the second 3D inductor 226 includes the third conductive layer 216, third conductive pillars 218 and 219, the fourth conductive layer 220, the second inductor bottom trace 232, or the second inductor top trace 238. There are also two regions that make up the second 3D inductor 226: a left second inductor region 226a and a right second inductor region 226b. There are two types of loops that can form the second 3D inductor 226: a “U” loop and an upside-down “U” loop.

The U loop for current flow in the second 3D inductor 226 is formed from the fourth conductive layer 220 of the left second inductor region 226a, through the third conductive pillar 218 of the left second inductor region 226a, through the third conductive layer 216 of the left second inductor region 226a, through the second inductor bottom trace 232, through the third conductive layer 216 of the right second inductor region 226b, through the third conductive pillar 219 of the right second inductor region 226b, through the fourth conductive layer 220 of the right second inductor region 226b to finally arrive at the third substrate 222. The U loop for the second 3D inductor 226 may also be formed in the opposite direction of what was just described.

The upside-down U loop for current flow in the second 3D inductor 226 is formed from the third conductive layer 216 of the left second inductor region 226a, through the third conductive pillar 218 of the left second inductor region 226a, through the fourth conductive layer 220 of the left second inductor region 226a, through the second inductor top trace 238, to the fourth conductive layer 220 of the right second inductor region 226b, through the third conductive pillar 219 of the right second inductor region 226b, and through the third conductive layer 216 of the right second inductor region 226b to finally arrive at the second substrate 214. The upside-down U loop for the second 3D inductor 226 may also be formed in the opposite direction.

The third 3D inductor 228 is made up of four regions: a bottom right third inductor region 228a, a top right third inductor region 228b, a top left third inductor region 228c, and a bottom left third inductor region 228d. The third 3D inductor 228 is also made up of a left second substrate package via 234, a right second substrate package via 236 and a third inductor trace 240.

The upside-down “U” loop for current flow in the third 3D inductor 228 is formed from the LGA 204 coupled to the right package via 206b, through the first conductive layer 208 of the bottom right third inductor region 228a, through the second conductive pillar 213 of the bottom right third inductor region 228a, through the second conductive layer 212 of the bottom right third inductor region 228a, and through the right second substrate package via 236. The current flow continues through the third conductive layer 216 of the top right third inductor region 228b, through the fourth conductive pillar 221 of the top right third inductor region 228b, through the fourth conductive layer 220 of the top right third inductor region 228b, and through the third inductor trace 240.

The flow continues through the fourth conductive layer 220 of the top left third inductor region 228c, through the fourth conductive pillar 223 of the top left third inductor region 228c, through the third conductive layer 216 of the top left third inductor region 228c, through the left second substrate package via 234, through the second conductive layer 212 of the bottom left third inductor region 228d, through the second conductive pillar 215 of the bottom left third inductor region 228d, and through the first conductive layer 208 of the bottom left third inductor region 228d to finally arrive at the first substrate 202. The upside-down U loop for the third 3D inductor 228 may also be formed in the opposite direction.

The third 3D inductor 228 has more inductance because its conductive loop is larger. Because additional stacks can be added to the device 200, 3D inductors with larger conductive loops and larger inductance values can be easily, quickly and conveniently formed.

In one implementation, the first substrate 202, the second substrate 214 and/or the third substrate 222 may be glass or other materials such as Silicon (Si), Gallium Arsenide (GaAs), Indium Phosphide (InP) Silicon Carbide (SiC), Sapphire (Al₂O₃), Quartz, Silicon on Insulator (SOI), Silicon on Sapphire (SOS), High Resistivity Silicon (HRS), Aluminum Nitride (AlN), a plastic substrate, a laminate, or a combination thereof. As described herein, the term “semiconductor substrate” may refer to a substrate of a diced wafer or may refer to the substrate of a wafer that is not diced. Similarly, the terms wafer and die may be used interchangeably unless such interchanging would tax credulity.

In one implementation, the conductive material of the first conductive pillars 210, 211, the second conductive pillars 213, 215, the third conductive pillars 218, 219, the fourth conductive pillars 221, 223, the first conductive layer 208, the second conductive layer 212, the third conductive layer 216 and the fourth conductive layer 220 may be Copper (Cu). In other configurations, the material is another conductive materials with high conductivity such as Silver (Ag), Gold (Au), Aluminum (Al), Tungsten (W), Nickel (Ni), and other like materials. Any of the conductive layers or conductive interconnects may be deposited upon a given substrate by electroplating, chemical vapor deposition (CVD), and/or physical vapor deposition (PVD), such as sputtering or evaporation.

The package vias 206a, 206b, 234 and 236 may be formed by a mask exposure and wet etch process involving chemicals able to etch the materials making up the various substrates. Alternatively, the package vias 206a, 206b, 234 and 236 can be formed by using a photodefinable polyimide (PI) during a photo development process (i.e., no dry or wet etch process is used).

There are a number of advantages associated with implementing 3D inductors as multiple stacks of pillars of conductive interconnect material. By creating 3D inductors from stacks of pillars, many more 3D inductors can be integrated into a given device or structure. In addition, the accumulative vertical height of a 3D inductor made from stacks of pillars (e.g., the third 3D inductor 228) can add up to a high Q factor. Also, 3D inductors implemented as multiple stacks of pillars (e.g., the third 3D inductor 228) exhibit much larger inductance values. Implementing 3D inductors as pillar stacks also creates more space in a device to implement a center tap region that couples to the 3D inductors within the device structure. The capacitor 110 shown in FIG. 2 is an example of such a center tap region component.

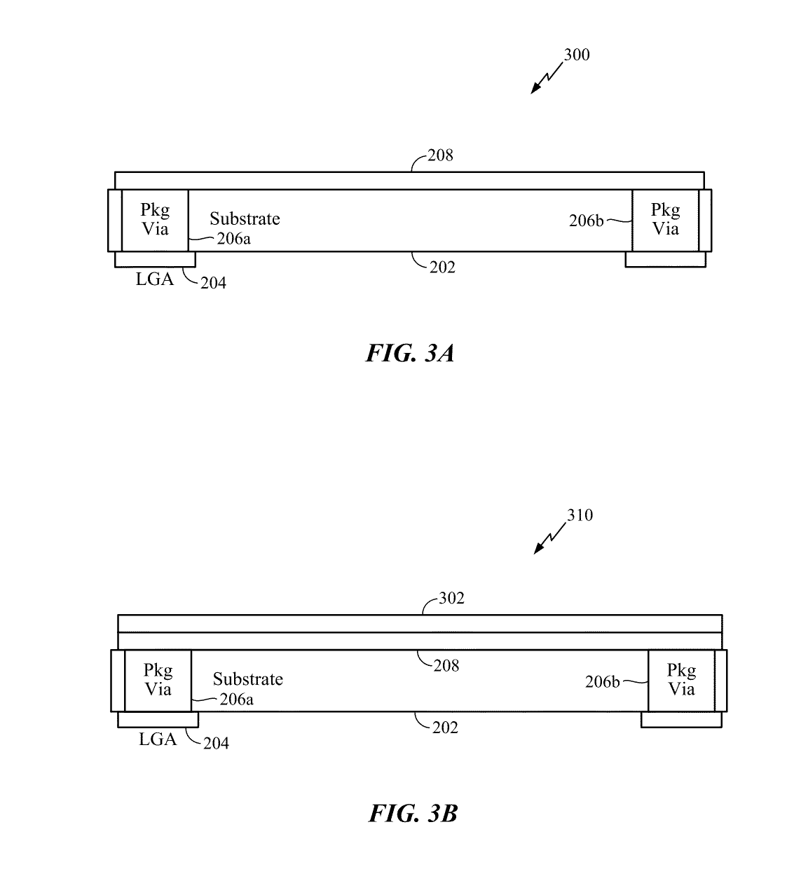

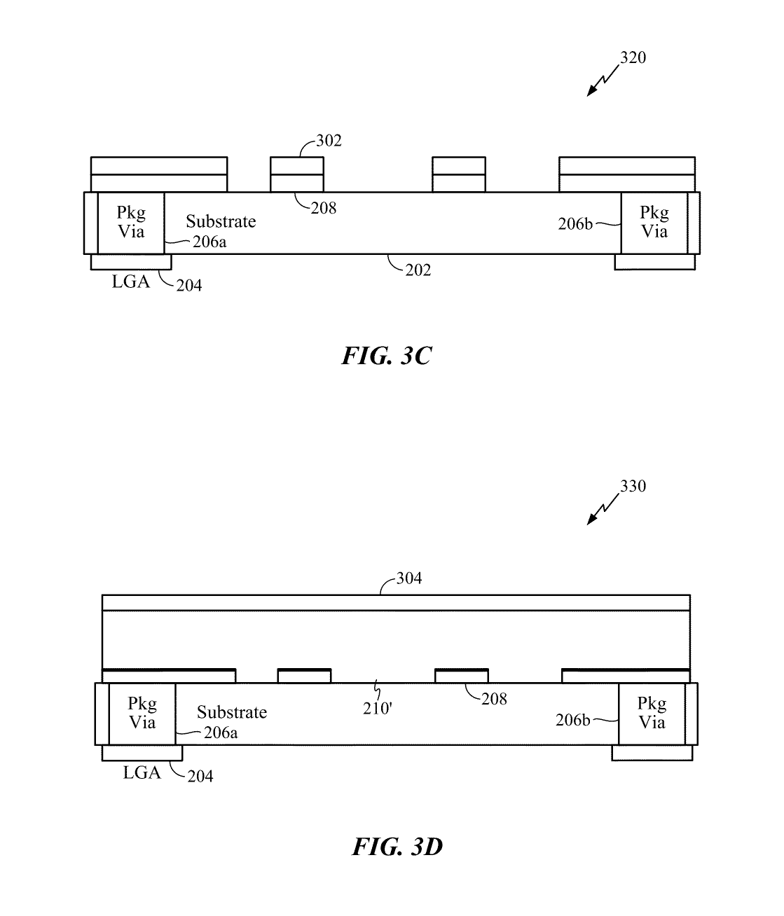

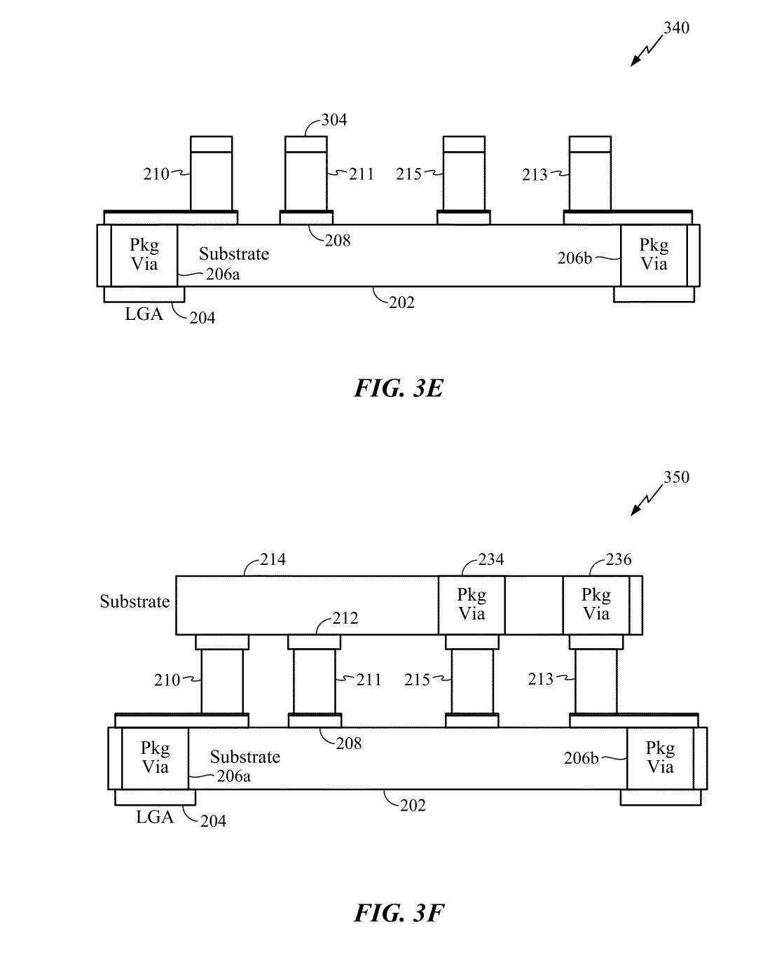

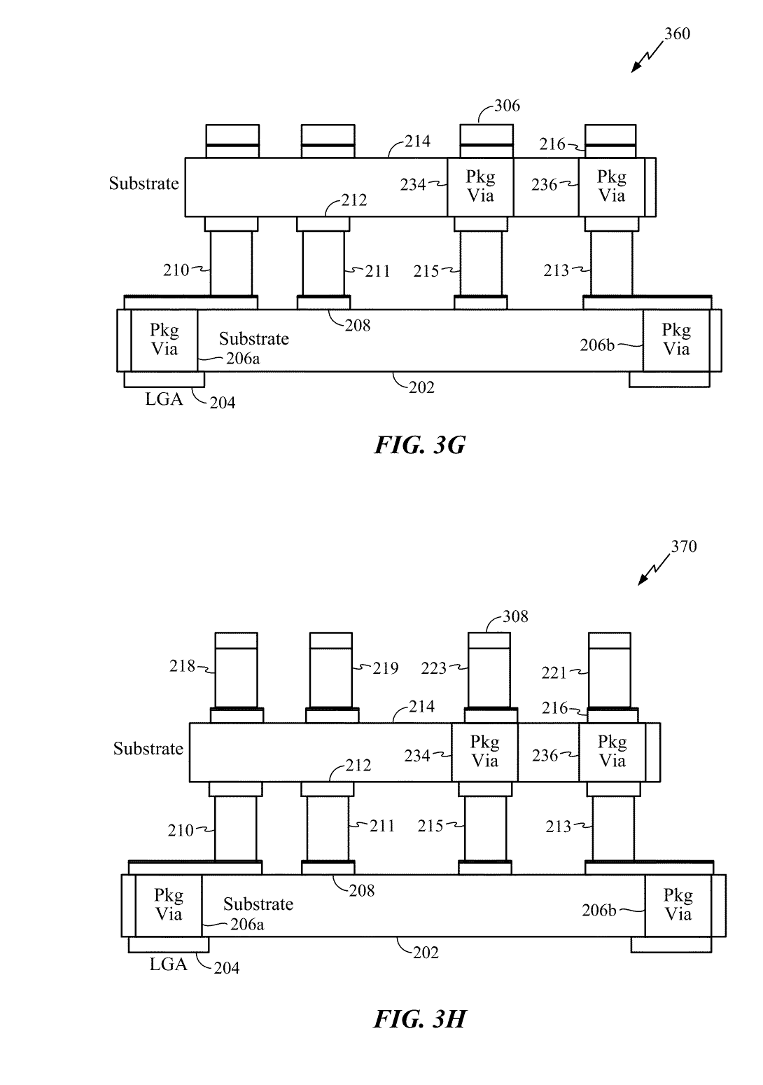

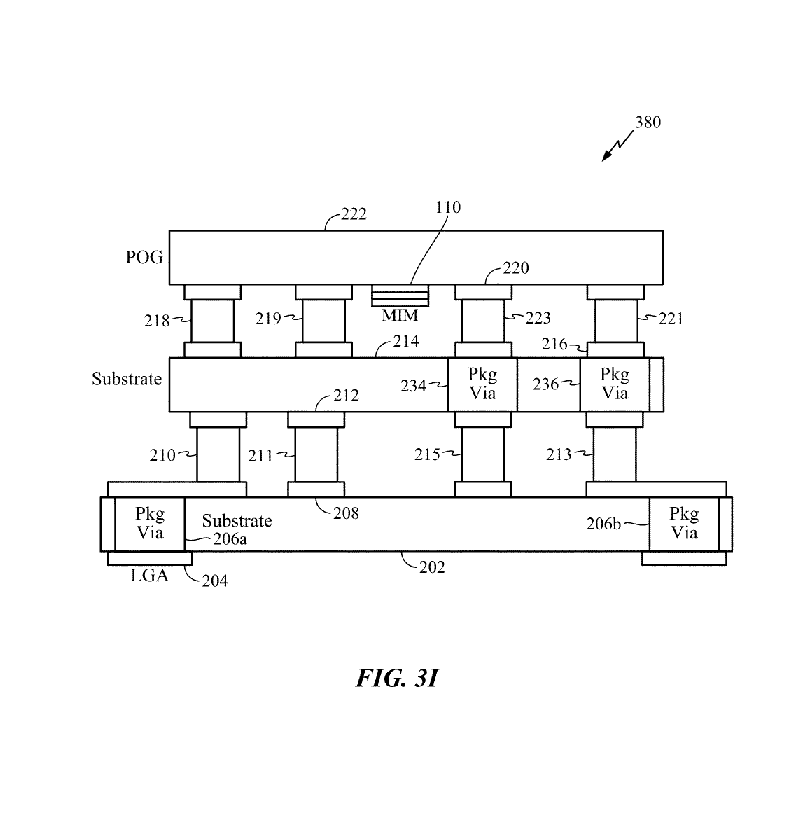

FIGS. 3A to 3I show cross-sectional views illustrating a process to fabricate a device having a multiple stack implementation of a 3D inductor according to one aspect of the disclosure.

In the cross-sectional view 300 of FIG. 3A, a first conductive layer 208 is deposited on a first substrate 202. The first conductive layer 208 may be deposited onto the first substrate 202 by electroplating, chemical vapor deposition (CVD), and/or physical vapor deposition (PVD), such as sputtering or evaporation. The first substrate 202 also is shown having at left package via 206a and a right package via 206b.

In the cross-sectional view 310 of FIG. 3B, a first photoresist layer 302 is deposited on the first conductive layer 208. The first photoresist layer 302 may be deposited by spin-coating, droplet-based photoresist deposition, and/or spraying.

In the cross-sectional view 320 of FIG. 3C, the first photoresist layer 302 is exposed by a mask in a photolithography process, and then the exposed portions are etched away by chemical etching processes using solutions such as photoresist developer, which may be made of, for example, Tetramethylammonium Hydroxide (TMAH), Iron Chloride (FeCl₃), Cupric Chloride (CuCl₂) or Alkaline Ammonia (NH₃). Dry etching processes using plasmas may also be used to etch the first photoresist layer 302. The first conductive layer 208 is then patterned by any wet chemical or dry etching process, with the etched photoresist regions of the first photoresist layer 302 being used as guidelines. The remaining portions of the first photoresist layer 302 may then be stripped (not shown) by a chemical photoresist stripping process using a photoresist stripper such as, for example, Positive Resist Stripper (PRS-2000), N-Methyl-2-Pyrrolidone (NMP), or Acetone. Photoresist layers may also be stripped by a dry photoresist stripping process using plasmas such as oxygen, which is known as ashing.

In the cross-sectional view 330 of FIG. 3D, a layer of first conductive material 210′ is deposited on the patterned regions of the first conductive layer 208. A second photoresist layer 304 is then deposited on the layer of the first conductive material 210′ to form first conductive pillars 210, 211 and second conductive pillars 213, 215, as shown in FIG. 3E. The first conductive material may be deposited by electroplating, chemical vapor deposition (CVD), and/or physical vapor deposition (PVD), such as sputtering or evaporation. The second photoresist layer 304 may be deposited by spin-coating, droplet-based photoresist deposition, and/or spraying.

In the cross-sectional view 340 of FIG. 3E, the second photoresist layer 304 is exposed by a mask in a photolithography process and then the exposed portions are etched away by chemical etching processes using solutions such as photoresist developer. Dry etching processes using plasmas may also be used to etch the second photoresist layer 304. The layer of first conductive material is then patterned by any wet chemical or dry etching process, with the etched photoresist regions of the second photoresist layer 304 being used as guidelines. The first conductive pillars 210, 211 and the second conductive pillars 213, 215 are formed as a result of this patterning. The remaining portions of the second photoresist layer 304 may then be stripped (not shown).

In the cross-sectional view 350 of FIG. 3F, a second conductive layer 212 is deposited and patterned on a second substrate 214. The second conductive layer 212 is patterned into regions that overlap with patterned regions of the first conductive layer 208 on the first substrate 202. In one implementation, as shown in FIG. 3F, the first conductive layer 208 flange regions on the far right and left sides of the first substrate 202 are not aligned with, and extend farther out than the patterned regions of the second conductive layer 212 on the far right and left sides of the second substrate 214. In another implementation, not shown in FIG. 3F, the regions of the first conductive layer 208 on the first substrate 202 align with the second conductive layer 212 regions on the second substrate 214. The patterned portions of the second conductive layer 212 adhere to the first conductive pillars 210, 211 and second conductive pillars 213, 215. In the second substrate 214, package vias 234 and 236 may be formed similar to how such package vias 206a and 206b are formed in the first substrate 202, such as by a wet chemical or dry etching process.

In the cross-sectional view 360 of FIG. 3G, a third conductive layer 216 is deposited on another surface of the second substrate 214. A third photoresist layer 306 is deposited on the third conductive layer 216. The third photoresist layer 306 and the third conductive layer 216 are then patterned and etched. The third photoresist layer 306 may then be stripped (not shown) by a chemical photoresist stripping or dry photoresist stripping process.

In the cross-sectional view 370 of FIG. 3H, a layer of second conductive material is deposited on patterned regions of the third conductive layer 216. A fourth photoresist layer 308 is then deposited on the layer of the second conductive material. The fourth photoresist layer 308 and the layer of the second conductive material are patterned and etched to form third conductive pillars 218, 219 and fourth conductive pillars 221, 223. The fourth photoresist layer 308 may then be stripped (not shown) by a chemical photoresist stripping or dry photoresist stripping process.

In the cross-sectional view 380 of FIG. 3I, a fourth conductive layer 220 is deposited and patterned on a third substrate 222. The fourth conductive layer 220 is patterned into regions that overlap or align with patterned regions of the third conductive layer 216 on the second substrate 214. In one implementation, as shown in FIG. 3I, all the third conductive layer 216 regions on the second substrate 214 align with all the fourth conductive layer 220 regions on the third substrate 222. In another implementation, as not shown in FIG. 3I, the third conductive layer 216 regions on the second substrate 214 may not align with all the fourth conductive layer 220 regions on the third substrate 222, like the regions of the first conductive layer 208 and the second conductive layer 212 as shown in FIG. 3I. The patterned portions of the fourth conductive layer 220 adhere to the third conductive pillars 218, 219 and the fourth conductive pillars 221, 223.

In the third substrate 222, package vias (not shown) may be formed similar to how such package vias 206a and 206b are formed in the first substrate 202 and package vias 234 and 236 are formed in the second substrate 214, such as by a wet chemical or dry etching process. In such a case, additional pillars and conductive layers may be added to further improve the Q factor and inductance.

Also in the cross-sectional view 380 of FIG. 3I, a metal-insulator-metal (MIM) capacitor 110 may be formed on the third substrate 222 by any semiconductor fabrication process used to deposit and pattern a MIM capacitor. The traces 230, 232, 238, 240 (not shown in FIGS. 3F-I) can be fabricated by depositing a conductive material at the appropriate locations.

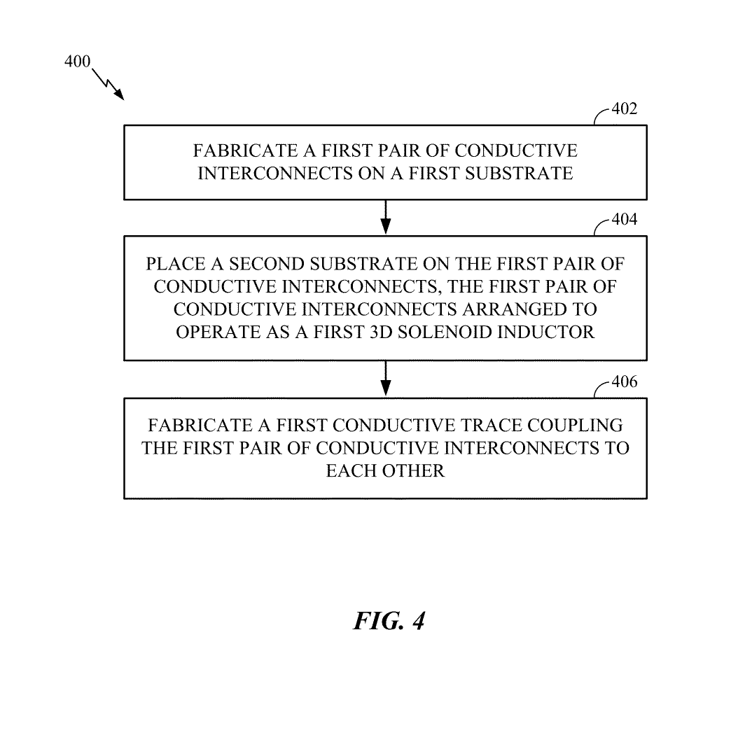

FIG. 4 is a process flow diagram illustrating a process 400 to fabricate a device having a multiple stack implementation of a 3D inductor according to one aspect of the disclosure. In block 402, a first pair of conductive interconnects (e.g., first conductive pillars 210 and 211) is fabricated on a first substrate (e.g., first substrate 202). In block 303, a second substrate (e.g., second substrate 214) is placed on the first pair of conductive interconnects with the first pair of conductive interconnects arranged to operate as a first 3D solenoid inductor (e.g., the first 3D inductor 224). In block 406, a first conductive trace (e.g., first inductor trace 230 or part of the first conductive trace may be the first inductor trace 230) is fabricated that couples the first pair of conductive interconnects to each other. This may be shown with reference to FIG. 2, or FIGS. 3A-3F.

In one configuration, an integrated circuit device includes a first substrate that supports a first pair of means for interconnecting. In one aspect of the disclosure, the means for interconnecting may be the first conductive pillars 210, 211, the second conductive pillars 213, 215, the third conductive pillars 218, 219 and/or the fourth conductive pillars 221, 223, as shown in FIG. 2 and FIG. 3I. The device also includes means for conducting. In one aspect of the disclosure, the conducting means may be the traces 230, 232, 238, 240 as shown in FIG. 2. In another aspect, the aforementioned means may be any circuitry or any apparatus configured to perform the functions recited by the aforementioned means.

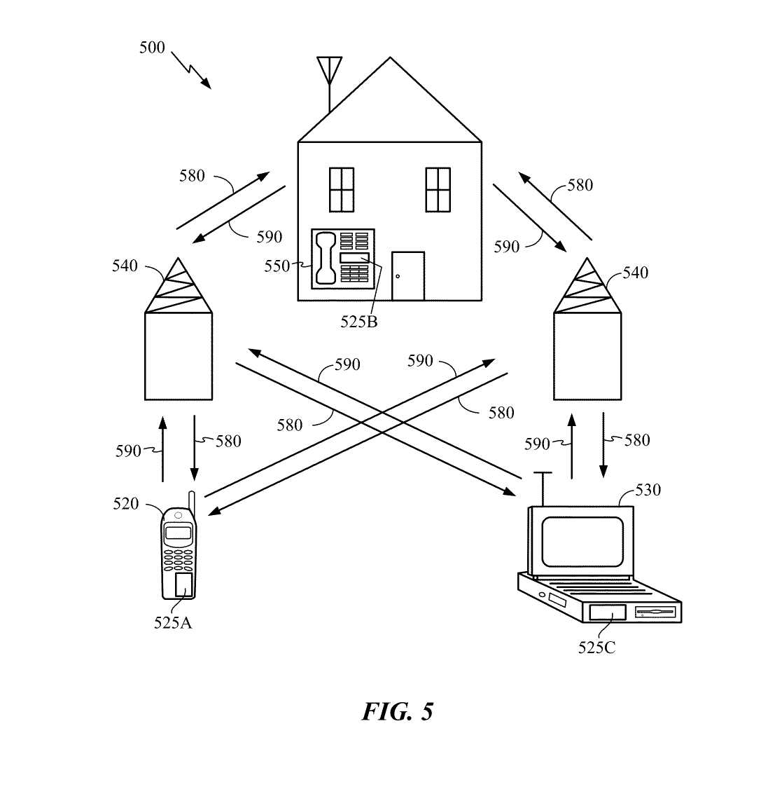

FIG. 5 is a block diagram showing an exemplary wireless communication system 500 in which an aspect of the disclosure may be advantageously employed. For purposes of illustration, FIG. 5 shows three remote units 520, 530, and 550 and two base stations 540. It will be recognized that wireless communication systems may have many more remote units and base stations. Remote units 520, 530, and 550 include IC devices 525A, 525C, and 525B that include the disclosed devices (e.g. 3D solenoid inductors). It will be recognized that other devices may also include the disclosed devices (e.g. 3D solenoid inductors), such as the base stations, switching devices, and network equipment. FIG. 5 shows forward link signals 580 from the base station 540 to the remote units 520, 530, and 550 and reverse link signals 590 from the remote units 520, 530, and 550 to base stations 540.

In FIG. 5, remote unit 520 is shown as a mobile telephone, remote unit 530 is shown as a portable computer, and remote unit 550 is shown as a fixed location remote unit in a wireless local loop system. For example, the remote units may be mobile phones, hand-held personal communication systems (PCS) units, portable data units such as personal data assistants, GPS enabled devices, navigation devices, set top boxes, music players, video players, entertainment units, fixed location data units such as meter reading equipment, or other devices that store or retrieve data or computer instructions, or combinations thereof. Although FIG. 5 illustrates remote units according to the aspects of the disclosure, the disclosure is not limited to these exemplary illustrated units. Aspects of the disclosure may be suitably employed in many devices, which include the disclosed devices.

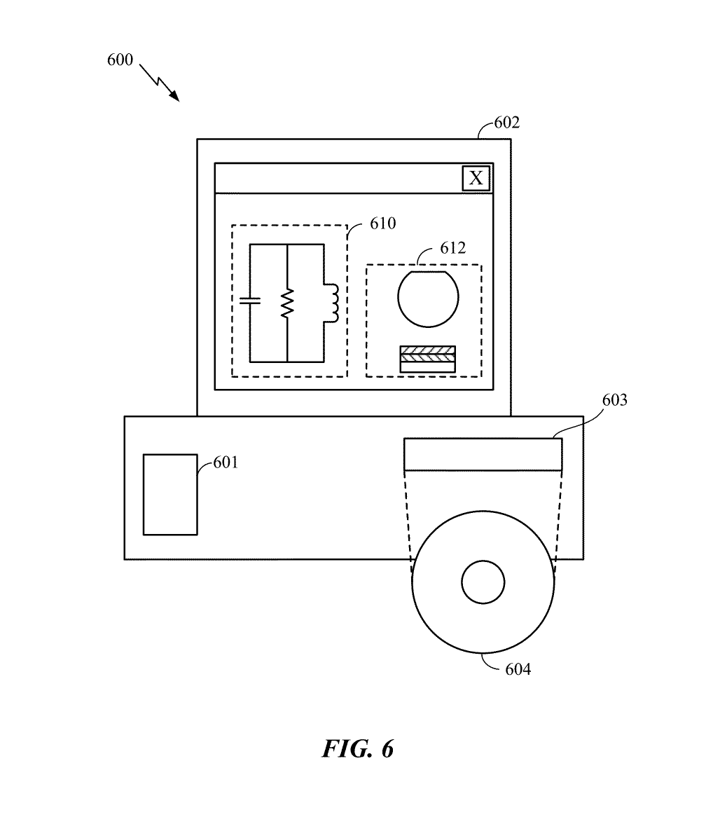

FIG. 6 is a block diagram illustrating a design workstation used for circuit, layout, and logic design of a semiconductor component, such as the 3D solenoid inductors disclosed above. A design workstation 600 includes a hard disk 601 containing operating system software, support files, and design software such as Cadence or OrCAD. The design workstation 600 also includes a display 602 to facilitate design of a circuit 610 or a semiconductor component 612 such as the disclosed device (e.g., a 3D solenoid inductor). A storage medium 604 is provided for tangibly storing the circuit design 610 or the semiconductor component 612. The circuit design 610 or the semiconductor component 612 may be stored on the storage medium 604 in a file format such as GDSII or GERBER. The storage medium 604 may be a CD-ROM, DVD, hard disk, flash memory, or other appropriate device. Furthermore, the design workstation 600 includes a drive apparatus 603 for accepting input from or writing output to the storage medium 604.

Data recorded on the storage medium 604 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 604 facilitates the design of the circuit design 610 or the semiconductor component 612 by decreasing the number of processes for designing semiconductor wafers.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

What is claimed is:

1. An integrated circuit device, comprising:
a first substrate supporting a first pair of conductive interconnects;
a second substrate on the first pair of conductive interconnects, the first pair of conductive interconnects arranged to operate as part of a first 3D solenoid inductor; and
a first conductive trace coupling the first pair of conductive interconnects to each other.

2. The integrated circuit device of claim 1, further comprising:
a second pair of conductive interconnects between the first substrate and the second substrate;
a third pair of conductive interconnects supported by the second substrate; and
a third substrate stacked on the second pair of conductive interconnects.

3. The integrated circuit device of claim 2, further comprising:
a second conductive trace coupling the third pair of conductive interconnects to each other, in which the third pair of conductive interconnects is arranged to operate as a second 3D solenoid inductor aligned with the first 3D solenoid inductor.

4. The integrated circuit device of claim 2, further comprising:
a second conductive trace coupling the second pair of conductive interconnects to each other, in which the second pair of conductive interconnects is arranged to operate as a second 3D solenoid inductor.

5. The integrated circuit device of claim 2, further comprising:
a fourth pair of conductive interconnects arranged between the second substrate and the third substrate and coupled to the second pair of conductive interconnects through a plurality of vias;
a second conductive trace coupling one end of the second pair of conductive interconnects to each other and that also goes through the fourth pair of conductive interconnects, the second pair of conductive interconnects and the fourth pair of conductive interconnects arranged to operate as a third 3D solenoid inductor having a height greater than a height of the first 3D solenoid inductor.

6. The integrated circuit device of claim 2, in which the third substrate comprises glass.

7. The integrated circuit device of claim 2, in which a metal-insulator-metal (MIM) capacitor is formed on a surface of the third substrate.

8. The integrated circuit device of claim 1, in which the first pair of conductive interconnects comprise a pair of pillars.

9. The integrated circuit device of claim 1 incorporated into at least one of a music player, a video player, an entertainment unit, a navigation device, a communications device, a personal digital assistant (PDA), a fixed location data unit, and a computer.

10. An integrated circuit device, comprising:
a first substrate supporting a first pair of conductive interconnects and a second pair of conductive interconnects;
a second substrate stacked on the first and second pair of conductive interconnects, the second substrate supporting a third pair of conductive interconnects and a fourth pair of conductive interconnects, the second substrate including a pair of vias coupling the second pair of conductive interconnects to the fourth pair of conductive interconnects;
a third substrate stacked on the third and fourth pairs of conductive interconnects;
a first conductive trace coupling the first pair of conductive interconnects to each other to operate as a first stacked 3D solenoid inductor;
a second conductive trace coupling the third pair of conductive interconnects to each other to operate as a second stacked 3D solenoid inductor; and
a third conductive trace coupling one of the second or fourth pair of conductive interconnects to each other to operate as a third stacked 3D solenoid inductor.

11. A back end of line processing method to fabricate an inductive device, comprising:
fabricating a first pair of conductive interconnects on a first substrate;
placing a second substrate on the first pair of conductive interconnects, the first pair of conductive interconnects arranged to operate as a first 3D solenoid inductor; and
fabricating a first conductive trace coupling the first pair of conductive interconnects to each other.

12. The method of claim 11, in which fabricating the first pair of conductive interconnects on the first substrate comprises:
depositing a first conductive layer on the first substrate;
depositing a first photoresist layer on the first conductive layer;
etching the first photoresist layer to pattern the first conductive layer;
stripping the first photoresist layer;
depositing a first interconnect material layer on the patterned first conductive layer;
depositing a second photoresist layer on the deposited first interconnect material layer; and
etching the second photoresist layer to pattern the first interconnect material layer to form the first pair of conductive interconnects.

13. The method of claim 11, further comprising:
fabricating a second pair of conductive interconnects between the first substrate and the second substrate;
fabricating a third pair of conductive interconnects on the second substrate; and
placing a third substrate on the third pair of conductive interconnects.

14. The method of claim 13, further comprising:
fabricating a second conductive trace coupling the third pair of conductive interconnects to each other, in which the third pair of conductive interconnects is arranged to operate as a second 3D solenoid inductor aligned with the first 3D solenoid inductor.

15. The method of claim 13, further comprising:
fabricating a second conductive trace coupling the second pair of conductive interconnects to each other, in which the second pair of conductive interconnects is arranged to operate as a second 3D solenoid inductor.

16. The method of claim 13, further comprising:
fabricating a fourth pair of conductive interconnects between the second substrate and the third substrate;
fabricating a plurality of vias in the second substrate;
coupling the fourth pair of conductive interconnects to the second pair of conductive interconnects through the plurality of vias; and
fabricating a second conductive trace coupling one end of the second pair of conductive interconnects to each other and that also goes through the fourth pair of conductive interconnects, the second pair of conductive interconnects and the fourth pair of conductive interconnects arranged to operate as a third 3D solenoid inductor having a height greater than a height of the first 3D solenoid inductor.

17. The method of claim 11, further comprising incorporating the inductive device into at least one of a music player, a video player, an entertainment unit, a navigation device, a communications device, a personal digital assistant (PDA), a fixed location data unit, and a computer.

18. An integrated circuit device, comprising:
a first substrate supporting a first pair of means for interconnecting;
a second substrate on the first pair of interconnecting means, the first pair of interconnecting means arranged to operate as a first 3D solenoid inductor; and
a first conductive means coupling the first pair of interconnecting means to each other.

19. The integrated circuit device of claim 18, further comprising:
a second pair of means for interconnecting between the first substrate and the second substrate;
a third pair of means for interconnecting supported by the second substrate; and
a third substrate stacked on the second pair of interconnecting means.

20. The integrated circuit device of claim 19, further comprising:
a second conductive means coupling the third pair of interconnecting means to each other, in which the third pair of interconnecting means is arranged to operate as a second 3D solenoid inductor aligned with the first 3D solenoid inductor.

21. The integrated circuit device of claim 19, further comprising:
a second conductive means coupling the second pair of interconnecting means to each other, in which the second pair of interconnecting means is arranged to operate as a second 3D solenoid inductor.

22. The integrated circuit device of claim 19, further comprising:
a fourth pair of means for interconnecting arranged between the second substrate and the third substrate and coupled to the second pair of interconnecting means through a plurality of vias; and
a second conductive means coupling one end of the second pair of interconnecting means to each other and that also goes through the fourth pair of interconnecting means, the second pair of interconnecting means and the fourth pair of interconnecting means arranged to operate as a third 3D solenoid inductor having a height greater than a height of the first 3D solenoid inductor.

23. The integrated circuit device of claim 19, in which the third substrate comprises glass.

24. The integrated circuit device of claim 19, in which a metal-insulator-metal (MIM) capacitor is formed on a surface of the third substrate.

25. The integrated circuit device of claim 18, in which the first pair of interconnecting means comprise a pair of pillars.

26. The integrated circuit device of claim 18 incorporated into at least one of a music player, a video player, an entertainment unit, a navigation device, a communications device, a personal digital assistant (PDA), a fixed location data unit, and a computer.
